(19) United States
(12) Patent Application Publication
(10) Pub. No.: US 2012/0168937 A1
(43) Pub. Date: Jul. 5, 2012

(54) FLIP CHIP PACKAGE AND METHOD OF MANUFACTURING THE SAME

(75) Inventor: Yong-Kwan LEE, Hwaseong-si (KR)

(73) Assignee: SAMSUNG ELECTRONICS CO., LTD., Suwon-si (KR)

(21) Appl. No.: 13/323,414

(22) Filed: Dec. 12, 2011

(30) Foreign Application Priority Data
Jan. 3, 2011 (KR) 10-2011-0000079

(51) Int. Cl. H01L 23/485; B23K 1/20

(52) U.S. Cl. 257/737; 228/246; 228/244; 257/E23.021

(57) ABSTRACT

A flip chip package and a method of manufacturing the same are provided. The flip chip package include: a package substrate, a semiconductor chip and conductive hollow bumps. The semiconductor chip may be arranged over an upper surface of the package substrate. The conductive hollow bumps may be interposed between the semiconductor chip and the package substrate to electrically connect the semiconductor chip with the package substrate. Thus, a wide gap may be formed between the semiconductor chip and the package substrate by the thick conductive hollow bumps. As a result, a sufficient amount of the molding member may be supplied to each of the conductive hollow bumps to surround each of the conductive hollow bumps.

### CROSS-REFERENCE TO RELATED APPLICATION

This application claims priority from Korean Patent Application No. 10-2011-0000079, filed on Jan. 3, 2011 in the Korean Intellectual Property Office (KIPO), the contents of which are herein incorporated by reference in their entirety.

### BACKGROUND

1. Field

Exemplary embodiments relate to a flip chip package and a method of manufacturing the same. More particularly, exemplary embodiments relate to a flip chip package including a semiconductor chip, a package substrate and conductive bumps, and a method of manufacturing the flip chip package.

2. Description of the Related Art

Generally, a plurality of semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages.

The semiconductor package may include a conductive connecting member for electrically connecting the semiconductor chip with a package substrate. The conductive connecting member may include a conductive wire, a conductive bump, etc. A semiconductor package having the conductive bump that may be interposed between the package substrate and the semiconductor chip may be referred to as a flip chip package.

In order to protect the semiconductor chip and the conductive bump from an external environment, a molding member may be formed on the package substrate. Further, in order to prevent an electrical short between the conductive bumps, the molding member may independently surround each of the conductive bumps.

However, as a design rule of a pattern in the semiconductor chip may have a reduced size, the conductive bumps may have a thin thickness and a pitch between the conductive bumps may be narrowed. That is, a gap between the semiconductor chip and the package substrate may be decreased. Thus, the molding member may not be sufficiently supplied between the semiconductor chip and the package substrate, so that the electrical short between the conductive bumps may be frequently generated. In contrast, when the conductive bumps have a sufficiently thick thickness to form a wide gap between the semiconductor chip and the package substrate, the thick conductive bumps in a small area may collapse.

### SUMMARY

Exemplary embodiments provide a flip chip package capable of forming a wide gap between a semiconductor chip and a package substrate using thick conductive bumps that may not collapse.

Exemplary embodiments also provide a method of manufacturing the above-mentioned flip chip package.

According to an aspect of an exemplary embodiment, there is provided a flip chip package. The flip chip package may include a package substrate, a semiconductor chip and conductive hollow bumps. The semiconductor chip may be arranged over an upper surface of the package substrate. The conductive hollow bumps may be interposed between the semiconductor chip and the package substrate to electrically connect the semiconductor chip with the package substrate.

In one or more exemplary embodiments, the flip chip package may further include filling members in the conductive hollow bumps. The filling members may include a solvent.

In one or more exemplary embodiments, the flip chip package may further include a molding member formed on the upper surface of the package substrate to cover the semiconductor chip and the conductive hollow bumps.

In one or more exemplary embodiments, the flip chip package may further include external terminals mounted on a lower surface of the package substrate. Each of the external terminals may include a hollow ball mounted on the lower surface of the package substrate, and a filling member in the hollow ball.

According to an aspect of another exemplary embodiment, there is provided a flip chip package. The flip chip package may include a package substrate, a first semiconductor chip, first conductive hollow bumps, a second semiconductor chip and second conductive hollow bumps. The first semiconductor chip may be arranged over an upper surface of the package substrate. The first semiconductor chip may have a plug formed through the first semiconductor chip. The first conductive hollow bumps may be interposed between the first semiconductor chip and the package substrate to electrically connect the first semiconductor chip with the package substrate. The second semiconductor chip may be arranged over an upper surface of the first semiconductor chip. The second conductive hollow bumps may be interposed between the second semiconductor chip and the first semiconductor chip to electrically connect the plug with the second semiconductor chip.

In one or more exemplary embodiments, the flip chip package may further include first filling members in the first conductive hollow bumps, and second filling member in the second conductive hollow bumps.

In one or more exemplary embodiments, the flip chip package may further include a molding member formed on the upper surface of the package substrate to cover the first semiconductor chip, the second semiconductor chip, the first conductive hollow bumps and the second conductive hollow bumps.

In one or more exemplary embodiments, the flip chip package may further include external terminals mounted on a lower surface of the package substrate. Each of the external terminals may include a hollow ball mounted on the lower surface of the package substrate, and a filling member in the hollow ball.

According to an aspect of another exemplary embodiment, there is provided a flip chip package. The flip chip package may include a package substrate, a first semiconductor chip, first conductive hollow bumps, an interposer chip, hollow interposer bumps, a second semiconductor chip and second conductive hollow bumps. The first semiconductor chip may be arranged over an upper surface of the package substrate. The first semiconductor chip may have a plug formed through the first semiconductor chip. The first conductive hollow bumps may be interposed between the first semiconductor chip and the package substrate to electrically connect the first semiconductor chip with the package substrate. The interposer chip may be arranged over an upper surface of the first semiconductor chip. The interposer chip may have an interposer plug formed through the interposer chip. The hollow interposer bumps may be interposed between the interposer chip and the first semiconductor chip to electrically connect the plug with the interposer plug. The second semiconductor chip may be arranged over an upper surface of the interposer chip. The second conductive hollow bumps may be interposed between the second semiconductor chip and the interposer chip to electrically connect the interposer plug with the second semiconductor chip.

In one or more exemplary, the flip chip package may further include first filling members in the first conductive hollow bumps, interposer-filling members in the hollow interposer bumps and second filling member in the second conductive hollow bumps.

In one or more exemplary, the flip chip package may further include a molding member formed on the upper surface of the package substrate to cover the first semiconductor chip, the interposer chip, the second semiconductor chip, the first conductive hollow bumps, the hollow interposer bumps and the second conductive hollow bumps.

In one or more exemplary embodiments, the flip chip package may further include external terminals mounted on a lower surface of the package substrate.

According to an aspect of another exemplary embodiment, there is provided a method of manufacturing a flip chip package. In the method of manufacturing the flip chip package, a semiconductor chip may be arranged over an upper surface of a package substrate. Conductive hollow bumps may be formed between the semiconductor chip and the package substrate to electrically connect the semiconductor chip with the package substrate via the conductive hollow bumps.

In one or more exemplary embodiments, forming the conductive hollow bumps may include forming a conductive paste containing a filling members on the upper surface of the package substrate, forming preliminary bumps on the conductive paste, attaching the semiconductor chip to the preliminary bumps, and performing a reflow process on the preliminary bumps and the conductive paste to expand the filling members into the preliminary bumps.

In one or more exemplary embodiments, the method may further include forming a molding member on the upper surface of the package substrate to cover the semiconductor chip and the conductive hollow bumps.

In one or more exemplary embodiments, the method may further include mounting external terminals on a lower surface of the package substrate. Mounting the external terminals may include forming a conductive paste containing filling members on the lower surface of the package substrate, forming preliminary bumps on the conductive paste, and performing a reflow process on the preliminary bumps and the conductive paste to expand the filling members into the preliminary bumps.

According to an aspect of another exemplary embodiment, there is provided a method of forming a conductive hollow bump for a flip chip package, the method including: providing a conductive paste containing a filling member on a first surface; providing a preliminary bump on the conductive paste; attaching a second surface to the preliminary bump; and performing a reflow process on the preliminary bump and the conductive paste to expand the filling member into the preliminary bump in order to form the conductive hollow bump to electrically connect the first surface to the second surface.

According to one or more exemplary embodiments, the conductive hollow bump may have a sufficient thick thickness and a collapse-resistive structure. Thus, a wide gap may be formed between the semiconductor chip and the package substrate by the thick conductive hollow bumps. As a result, a sufficient amount of the molding member may be supplied to each of the conductive hollow bumps to surround each of the conductive hollow bumps.

### BRIEF DESCRIPTION OF THE DRAWINGS

Exemplary embodiments will be more clearly understood from the following detailed description taken in conjunction with the accompanying drawings. FIGS. 1 to 9 represent non-limiting, exemplary embodiments as described herein.

FIG. 1 is a cross-sectional view illustrating a flip chip package in accordance with an exemplary embodiment;

FIG. 2 is an enlarged cross-sectional view of a portion “II” in FIG. 1 in accordance with an exemplary embodiment;

FIGS. 3 to 7 are cross-sectional views illustrating a method of manufacturing the flip chip package in FIG. 1 in accordance with one or more exemplary embodiments;

FIG. 8 is a cross-sectional view illustrating a flip chip package in accordance with another exemplary embodiment; and

FIG. 9 is a cross-sectional view illustrating a flip chip package in accordance with still another exemplary embodiment.

### DETAILED DESCRIPTION OF EXEMPLARY EMBODIMENTS

Various exemplary embodiments will be described more fully hereinafter with reference to the accompanying drawings, in which some exemplary embodiments are shown. An exemplary embodiment may, however, be embodied in many different forms and should not be construed as limited to the exemplary embodiments set forth herein. Rather, these exemplary embodiments are provided so that this disclosure will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result of, for example, manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

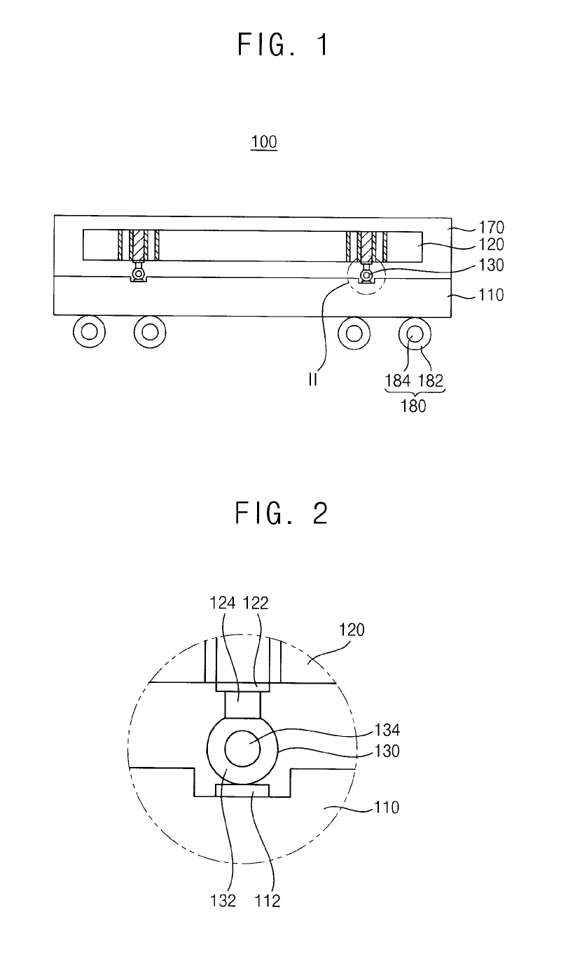

FIG. 1 is a cross-sectional view illustrating a flip chip package 100 in accordance with an exemplary embodiment, and FIG. 2 is an enlarged cross-sectional view of a portion “II” in FIG. 1.

Referring to FIGS. 1 and 2, a flip chip package 100 of the present exemplary embodiment may include a package substrate 110, a semiconductor chip 120, conductive hollow bumps 130, a molding member 170 and external terminals 180.

The package substrate 110 may include a circuit pattern (not shown). Upper pads 112 may be formed on an upper surface of the package substrate 110. The upper pads 112 may be electrically connected to the circuit pattern. Lower pads (not shown) may be formed on a lower surface of the package substrate 110. The lower pads may be electrically connected to the circuit pattern.

The semiconductor chip 120 may be arranged over the upper surface of the package substrate 110. Pads 122 may be formed on a lower surface of the semiconductor chip 120. Thus, the pads 122 may be oriented toward the package substrate 110 (i.e., on a surface of the semiconductor chip 120 facing the package substrate 110). A conductive post 124 may be formed on a lower surface of each of the pads 112. In one or more exemplary embodiments, the conductive post 124 may include a metal such as copper.

The conductive hollow bumps 130 may be interposed between the conductive post 124 and the upper pad 112 of the package substrate 110 to electrically connect the semiconductor chip 120 with the package substrate 110. The conductive hollow bumps 130 may be directly interposed between the conductive post 124 and the upper pad 112, or there may be one or more conductive elements between the conductive hollow bumps 130 and at least one of the conductive post 124 and the upper pad 112. In one or more exemplary embodiments, the conductive hollow bumps 130 may include solder bumps.

Each of the conductive hollow bumps 130 may have an inner space 132. A filling member 134 may be filled in the inner space 132 of the conductive hollow bump 130. In one or more exemplary embodiments, the filling member 134 may include solvent.

In one or more exemplary embodiments, the inner space 132 of the conductive hollow bump 130 may be formed by expanding the filling member 134 into a preliminary bump during a reflow process. Thus, the conductive hollow bump 130 may have a thick thickness and a collapse-resistive structure. As a result, the thick conductive hollow bump 130 may form a sufficient gap between the package substrate 110 and the semiconductor chip 120.

The molding member 170 may be formed on the upper surface of the package substrate 110 to cover the semiconductor chip 120 and the conductive hollow bumps 130. In one or more exemplary embodiments, the molding member 170 may individually surround each of the conductive hollow bumps 130 to prevent an electrical short between the conductive hollow bumps 130. The molding member 170 may include an epoxy molding compound (EMC).

In one or more exemplary embodiments, because a sufficiently wide gap may be formed between the package substrate 110 and the semiconductor chip 120 due to the thickness of the conductive hollow bumps 130, a sufficient amount of the molding member 170 may be supplied into the wide gap between the package substrate 110 and the semiconductor chip 120. As a result, the molding member 170 may individually surround each of the conductive hollow bumps 130 to prevent the electrical short between the conductive hollow bumps 130.

The external terminals 180 may be mounted on the lower pads of the package substrate 110. In one or more exemplary embodiments, each of the external terminals 180 may include a hollow ball 182 formed on the lower pad, and a filling member 184 in the hollow ball 182. The filling member 184 may include solvent. The hollow ball 182 may include a solder ball. Alternatively, the external terminals 180 may include solid balls.

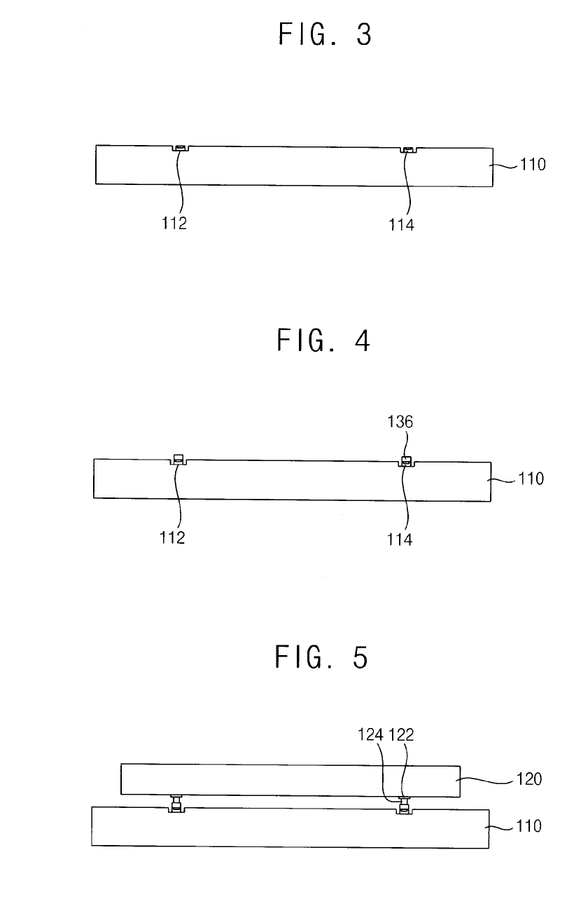

FIGS. 3 to 7 are cross-sectional views illustrating a method of manufacturing the flip chip package in FIG. 1 in accordance with one or more exemplary embodiments.

Referring to FIG. 3, a conductive paste 114 may be formed on the upper pad 112 of the package substrate 110. In one or more exemplary embodiments, the conductive paste 114 may include a solvent. Alternatively, the upper pad 112 may include the conductive paste 114.

Referring to FIG. 4, a preliminary bump 136 may be arranged on the conductive paste 114. In one or more exemplary embodiments, the preliminary bump 134 may have a solid structure. The preliminary bump 136 may include a solder bump.

Referring to FIG. 5, the conductive post 124 of the semiconductor chip 120 may be attached to the preliminary bump 136.

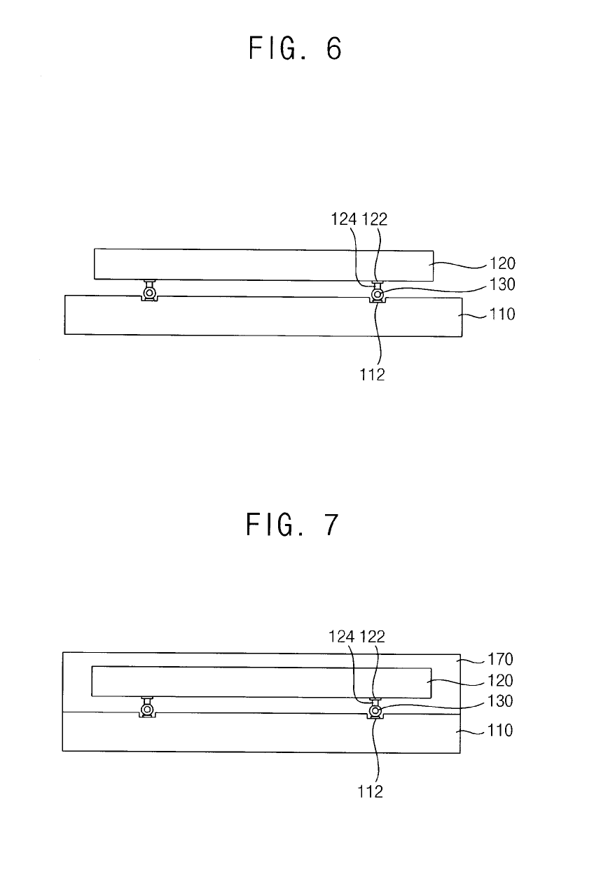

Referring to FIG. 6, a reflow process may be performed on the preliminary bump 136. During the reflow process, heat may be applied to the preliminary bump 136 and the conductive paste 114, so that the solvent in the conductive paste 114 may expand into the preliminary bump 136 to form the conductive hollow bump 130. That is, the filling member 134 corresponding to the solvent may be filled in the inner space of the preliminary bump 136 to form the conductive hollow bump 130.

In one or more exemplary embodiments, the conductive hollow bump 130 may be formed by expanding the solvent into the preliminary bump 136. Thus, the conductive hollow bump 130 may have a sufficiently thick thickness and a collapse-resistive structure in a small area. As a result, a sufficiently wide gap may be formed between the package substrate 110 and the semiconductor chip 120 by the conductive hollow bump 130. The thickness of the conductive hollow bump 130 may be determined in accordance with the expansion of the solvent, so that the thickness of the conductive hollow bump 130 may vary by controlling an amount of the conductive paste 114.

Referring to FIG. 7, the molding member 170 may be formed on the upper surface of the package substrate 110 to cover the semiconductor chip 120 and the conductive hollow bump 130. In one or more exemplary embodiments, as mentioned above, because the sufficiently wide gap may be formed between the package substrate 110 and the semiconductor chip 120, a sufficient amount of the molding member 170 may be supplied to the gap between the package substrate 110 and the semiconductor chip 120. Thus, the molding member 170 may individually surround each of the conductive hollow bumps 130 to prevent the electrical short between the conductive hollow bumps 130.

The external terminals 180 may be mounted on the lower surface of the package substrate 110 to complete the flip chip package 100 in FIG. 1. In one or more exemplary embodiments, processes for forming the external terminals 180 may be substantially similar to those for forming the conductive hollow bumps 130. Thus, a description of the processes for forming the external terminals 180 is omitted herein for brevity.

According to the present exemplary embodiment, the conductive hollow bump 130 may have a sufficiently thick thickness and a collapse-resistive structure. Thus, a wide gap may be formed between the semiconductor chip 120 and the package substrate 100 by the thick conductive hollow bumps 130. As a result, a sufficient amount of the molding member 170 may be supplied to each of the conductive hollow bumps 130 to surround each of the conductive hollow bumps 130.

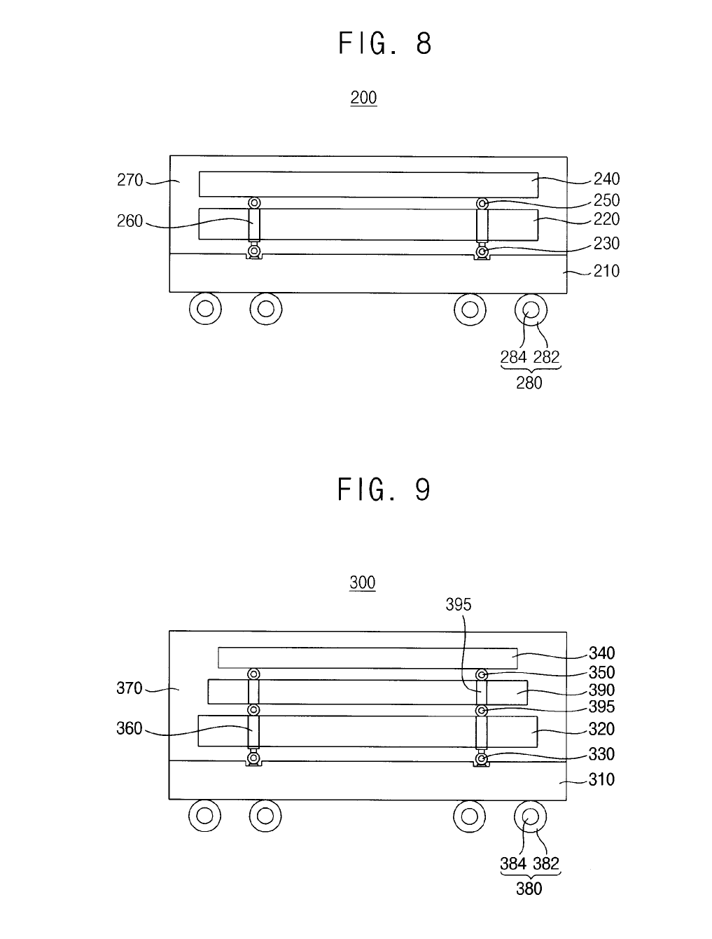

FIG. 8 is a cross-sectional view illustrating a flip chip package in accordance with another exemplary embodiment.

Referring to FIG. 8, a flip chip package 200 of the present exemplary embodiment may include a package substrate 210, a first semiconductor chip 220, first conductive hollow bumps 230, a second semiconductor chip 240, second conductive hollow bumps 250, a molding member 270 and external terminals 280.

In one or more exemplary embodiments, the package substrate 210, the first conductive hollow bumps 230, the molding member 270 and the external terminals 280 may be substantially the same as the package substrate 110, the conductive hollow bumps 130, the molding member 170 and the external terminals 180 in FIG. 1, respectively. Thus, any further illustrations and descriptions with respect to the package substrate 210, the first conductive hollow bumps 230, the molding member 270 and the external terminals 280 are omitted herein for brevity.

The first semiconductor chip 220 may include a plug 260. In one or more exemplary embodiments, the plug 260 may be vertically provided in the first semiconductor chip 220. Thus, the plug 260 may have a lower end configured to make contact with a pad of the first semiconductor chip 220, and an upper end exposed through an upper surface of the first semiconductor chip 220.

The second semiconductor chip 240 may be arranged over the upper surface of the first semiconductor chip 220. In one or more exemplary embodiments, the second semiconductor chip 240 may have a size substantially the same as that of the first semiconductor chip 220, though it is understood that another exemplary embodiment is not limited thereto.

The second conductive hollow bumps 250 may be interposed between the plug 260 and a pad (not shown) of the second semiconductor chip 240 to electrically connect the first semiconductor chip 220 with the second semiconductor chip 240. In one or more exemplary embodiments, the second conductive hollow bumps 250 may have a structure substantially the same as that of the first conductive hollow bumps 230. Thus, any further illustrations and descriptions with respect to the second conductive hollow bumps 250 are omitted herein for brevity.

In one or more exemplary embodiments, the second conductive hollow bumps 250 may have a thick thickness and a collapse-resistive structure substantially similar to those of the first conductive hollow bumps 230. Therefore, a sufficiently wide gap may be formed between the first semiconductor chip 220 and the second semiconductor chip 240 by virtue of the second conductive hollow bumps 250. As a result, the molding member 270 may individually surround each of the second conductive hollow bumps 250 to prevent an electrical short between the second conductive hollow bumps 250.

FIG. 9 is a cross-sectional view illustrating a flip chip package 300 in accordance with still another exemplary embodiment.

Referring to FIG. 9, a flip chip package 300 of the present exemplary embodiment may include a package substrate 310, a first semiconductor chip 320, first conductive hollow bumps 330, an interposer chip 390, hollow interposer bumps 395, a second semiconductor chip 340, second conductive hollow bumps 350, a molding member 370 and external terminals 380.

In one or more exemplary embodiments, the package substrate 310, the first conductive hollow bumps 330, the molding member 370 and the external terminals 380 may be substantially the same as the package substrate 110, the conductive hollow bumps 130, the molding member 170 and the external terminals 180 in FIG. 1, respectively. Thus, any further illustrations and descriptions with respect to the package substrate 310, the first conductive hollow bumps 330, the molding member 370 and the external terminals 380 are omitted herein for brevity.

The first semiconductor chip 320 may include a plug 360. In one or more exemplary embodiments, the plug 360 may be vertically built in the first semiconductor chip 320. Thus, the plug 360 may have a lower end configured to make contact with a pad of the first semiconductor chip 320, and an upper end exposed through an upper surface of the first semiconductor chip 320.

The interposer chip 390 may be arranged over the upper surface of the first semiconductor chip 320. The interposer chip 390 may electrically connect the first semiconductor chip 320 and the second semiconductor chip 340, which may have different sizes, with each other. The interposer chip 390 may have an interposer plug 392. In one or more exemplary embodiments, the interposer plug 392 may be vertically built in the interposer chip 390. Thus, the interposer plug 392 may have a lower end exposed through a lower surface of the interposer chip 390, and an upper end exposed through an upper surface of the interposer chip 390.

The hollow interposer bumps 395 may be interposed between the plug 360 and the interposer plug 392 to electrically connect the first semiconductor chip 320 with the interposer chip 390. In one or more exemplary embodiments, the hollow interposer bumps 395 may have a structure substantially the same as that of the first conductive hollow bumps 330. Thus, any further illustrations and descriptions with respect to the hollow interposer bumps 395 are omitted herein for brevity.

In one or more exemplary embodiments, the hollow interposer bumps 395 may have a thick thickness and a collapse-resistive structure substantially similar to those of the first conductive hollow bumps 330. Therefore, a sufficiently wide gap may be formed between the first semiconductor chip 320 and the interposer chip 390 by virtue of the hollow interposer bumps 395. As a result, the molding member 370 may individually surround each of the hollow interposer bumps 395 to prevent an electrical short between the hollow interposer bumps 395.

The second semiconductor chip 340 may be arranged over the upper surface of the interposer chip 390. In one or more exemplary embodiments, the second semiconductor chip 340 may have a size smaller than that of the first semiconductor chip 320.

The second conductive hollow bumps 350 may be interposed between the interposer plug 395 and a pad (not shown) of the second semiconductor chip 340 to electrically connect the interposer chip 390 with the second semiconductor chip 340. In one or more exemplary embodiments, the second conductive hollow bumps 350 may have a structure substantially the same as that of the first conductive hollow bumps 330. Thus, any further illustrations and descriptions with respect to the second conductive hollow bumps 350 are omitted herein for brevity.

In one or more exemplary embodiments, the second conductive hollow bumps 350 may have a thick thickness and a collapse-resistive structure substantially similar to those of the first conductive hollow bumps 330. Therefore, a sufficiently wide gap may be formed between the interposer chip 390 and the second semiconductor chip 340 by virtue of the second conductive hollow bumps 350. As a result, the molding member 370 may individually surround each of the second conductive hollow bumps 350 to prevent an electrical short between the second conductive hollow bumps 350.

According to one or more exemplary embodiments, the conductive hollow bump may have a sufficiently thick thickness and a collapse-resistive structure. Thus, a wide gap may be formed between the semiconductor chip and the package substrate by the thick conductive hollow bumps. As a result, a sufficient amount of the molding member may be supplied to each of the conductive hollow bumps to surround each of the conductive hollow bumps.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A flip chip package comprising:
a package substrate;
a semiconductor chip arranged over a first surface of the package substrate; and
a conductive hollow bump interposed between the semiconductor chip and the package substrate to electrically connect the semiconductor chip with the package substrate.

2. The flip chip package of claim 1, further comprising a filling member in the conductive hollow bump.

3. The flip chip package of claim 2, wherein the filling member comprises a solvent.

4. The flip chip package of claim 1, further comprising a molding member on the first surface of the package substrate to cover the semiconductor chip and the conductive hollow bump.

5. The flip chip package of claim 1, further comprising an external terminal mounted on a second surface of the package substrate.

6. The flip chip package of claim 5, wherein the external terminal comprises:
a hollow ball mounted on the second surface of the package substrate; and
a filling member inside the hollow ball.

7. The flip package of claim 4, further comprising:
an adjacent conductive hollow bump adjacent to the conductive hollow bump and interposed between the semiconductor chip and the package substrate to electrically connect the semiconductor chip with the package substrate,
wherein the molding member individually surrounds each of the conductive hollow bump and the adjacent conductive hollow bump.

8. The flip package of claim 1, further comprising:
a first pad on a surface of the semiconductor chip facing the package substrate;
a conductive post interposed between the first pad and the conductive hollow bump; and
a second pad interposed between the conductive hollow bump and the first surface of the package substrate.

9. A flip chip package comprising:
a package substrate;
a first semiconductor chip arranged over a first surface of the package substrate, the first semiconductor chip having a plug;
a first conductive hollow bump interposed between the first semiconductor chip and the package substrate to electrically connect the plug with the package substrate;
an interposer chip arranged over a first surface of the first semiconductor chip, the interposer chip having an interposer plug;
a hollow interposer bump interposed between the interposer chip and the first semiconductor chip to electrically connect the plug with the interposer plug;
a second semiconductor chip arranged over the interposer chip; and
a second conductive hollow bump interposed between the second semiconductor chip and the interposer chip to electrically connect the interposer plug with the second semiconductor chip.

10. The flip chip package of claim 9, further comprising:
a first filling member in the first conductive hollow bump;
an interposer-filling member in the hollow interposer bump; and
a second filling member in the second conductive hollow bump.

11. The flip chip package of claim 9, further comprising a molding member on the first surface of the package substrate to cover the first semiconductor chip, the interposer chip, the second semiconductor chip, the first conductive hollow bump, the hollow interposer bump and the second conductive hollow bump.

12. The flip chip package of claim 9, further comprising an external terminal mounted on a second surface of the package substrate.

13. A method of manufacturing a flip chip package, the method comprising:
arranging a semiconductor chip over a first surface of a package substrate;
interposing a conductive hollow bump between the semiconductor chip and the package substrate to electrically connect the semiconductor chip with the package substrate.

14. The method of claim 13, wherein the interposing the conductive hollow bump comprises:
providing a conductive paste containing a filling member on the first surface of the package substrate;
providing a preliminary bump on the conductive paste;
attaching a semiconductor chip to the preliminary bump; and
performing a reflow process on the preliminary bump and the conductive paste to expand the filling member into the preliminary bump in order to form the conductive hollow bump.

15. The method of claim 13, further comprising forming a molding member on the first surface of the package substrate to cover the semiconductor chip and the conductive hollow bump.

16. The method of claim 13, further comprising mounting an external terminal on a second surface of the package substrate.

17. The method of claim 16, wherein the mounting the external terminal comprises:
providing a conductive paste containing a filling member on the second surface of the package substrate;
providing a preliminary bump on the conductive paste; and
performing a reflow process on the preliminary bump and the conductive paste to expand the filling member into the preliminary bump in order to form the external terminal.

18. The method of claim 14, wherein the providing the conductive paste comprises providing the conductive paste on a pad disposed on the first surface of the package substrate.

19. A method of forming a conductive hollow bump for a flip chip package, the method comprising:
providing a conductive paste containing a filling member on a first surface;
providing a preliminary bump on the conductive paste;
attaching a second surface to the preliminary bump; and
performing a reflow process on the preliminary bump and the conductive paste to expand the filling member into the preliminary bump in order to form the conductive hollow bump to electrically connect the first surface to the second surface.

20. A flip chip package comprising:
a package substrate;
a first semiconductor chip arranged over the package substrate, the first semiconductor chip having a plug;
a first conductive hollow bump interposed between the first semiconductor chip and the package substrate to electrically connect the plug with the package substrate;
a second semiconductor chip arranged over the first semiconductor chip; and
a second conductive hollow bump interposed between the second semiconductor chip and the first semiconductor chip to electrically connect the plug with the second semiconductor chip.
